(19) United States
(12) Patent Application Publication
(10) Pub. No.: US 2026/0243469 A1
(43) Pub. Date: Aug. 20, 2026

(54) SYSTEMS AND METHODS FOR A DEVICE HAVING SOLAR MATERIAL DISPLAYING VIVID IMAGES USING STRUCTURAL INK

(71) Applicants: Toyota Motor Engineering & Manufacturing North America, Inc., Plano, TX (US); Toyota Jidosha Kabushiki Kaisha, Toyota-shi Aichi-ken (JP)

(72) Inventors: Songtao Wu, Ann Arbor, MI (US); Debasish Banerjee, Ann Arbor, MI (US); Brian K. Woods, Brighton, MI (US); Ryota Tomizawa, Shizuoka-ken Susono-shi (JP)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 19/055,179

(22) Filed: Feb. 17, 2025

(51) Int. Cl. F24S 23/30; F24S 23/00; F24S 50/80; F24S 70/60; H02S 20/25

(52) U.S. Cl. CPC F24S 23/30; F24S 23/12; F24S 50/80; F24S 70/60; H02S 20/25

(57) ABSTRACT

Systems and other embodiments described herein relate to improving the aesthetics of absorption components that harvest solar energy by displaying an image formed with structural ink and a lens that selectively displays the image while directing light for energy capture. In one embodiment, the system includes a lens that directs incident light within a first angular range towards absorption components and a second angular range towards viewing material. The system also includes the viewing material applied to the lens within predetermined areas, the viewing material forms an image. The system also includes the viewing material being a color pigment having a reflector core that reflects the incident light at the second angular range within the predetermined areas. The system also includes the absorption components being located within and outside the predetermined areas, the absorption components capturing energy from the incident light within the first angular range.

### TECHNICAL FIELD

The subject matter described herein relates, in general, to capturing solar energy while displaying an image by a device, and, more particularly, to harvesting the solar energy and forming the image using structural ink with a lens for selectively displaying the image.

### BACKGROUND

Harvesting solar energy from captured light can power buildings and electronics. For example, incident light hits solar panels with photovoltaic material encapsulated in other materials (e.g., glass). The photovoltaic material releases electrons and generates an electric charge when exposed to photons from the incident light. Electric charge from the photons accumulates rapidly through solar panels that are sizable for powering devices such as consumer electronics, home lighting, etc. The electric charge can be a direct current (DC) for powering the consumer electronics. Furthermore, an inverter can transform the DC to alternating current (AC) in various forms for powering outlets in a building by geography. However, DC/AC output power from solar panels is correlated with the size and density of the photovoltaic material. As such, systems having demanding power loads are impacted and limited by the size of photovoltaic material.

Certain systems include a device array having photovoltaic material that expand capture areas. The device arrays can power a neighborhood when having capture areas that are expansive, but demand land and space for installations. Compact arrays on a residential roof can power smaller homes. Still, these systems exhibit poor appearances and aesthetics that limit installation sizes. Aesthetic qualities and crude designs of solar arrays can lead to permitting rules by neighborhoods and towns for protecting property values. For example, zoning and commercial laws restrict designs, limit size, and designate certain locations on buildings for solar installations. Thus, producing power from solar energy for devices demanding expansive installation areas can be hindered by aesthetics and designs.

### SUMMARY

In one embodiment, example systems and methods relate to improving the aesthetics of absorption components that harvest solar energy by displaying an image formed with structural ink and a lens that selectively displays the image while directing light for energy capture. In various implementations, devices harvesting solar energy with photovoltaic material generate output power that is constrained and inadequate. Unattractive aesthetics and limited flexibility constrain sizes associated with these devices and correspondingly limit output power. In another example, roofing and building materials attempt to hide solar arrays for enhancing aesthetics. However, hiding and camouflaging solar material using these systems may reduce efficiency for energy capture when blocking and obstructing incident light. Resolution and definition can decrease from blurring associated with manufacturing defects that hinder adoption. Rigid and inflexible properties also reduce installation sizes and locations to uniform and flat areas.

Therefore, in one embodiment, a system includes a lens that selectively directs light to absorption components that capture solar energy and an image printed using structural ink as viewing material. The lens can pass incident light to the absorption components at certain angles while directing the light towards the image at other angles. This allows effectively hiding the absorption components through displaying the image by obstructing the incident light using the lens. In one approach, the structural ink is formed with a reflector core having metallic and dielectric elements using physical vapor deposition (PVD). Here, the structural ink avoids adding reflective components to the lens for improving image clarity and sharpness. In another approach, the structural ink has the reflector core near metallic material in a symmetric form using atomic layer deposition (ALD). As such, the reflector core naturally provides reflective properties for increasing image vividness. Furthermore, the system can have the absorption components bonded to the lens and the structural ink, such as with an optical adhesive. In this way, the system allows for improved aesthetic integration with superior energy retention during solar harvesting. Accordingly, the system displays an image at certain viewing angles without reducing solar capture and improves aesthetics for solar devices while reducing manufacturing complexity through applying structural ink having reflective properties for forming the image.

In one embodiment, a system for improving the aesthetics of absorption components that harvest solar energy by displaying an image formed with structural ink and a lens that selectively displays the image while directing light for energy capture is disclosed. In one embodiment, the system includes a lens that directs incident light within a first angular range towards absorption components and a second angular range towards viewing material. The system also includes the viewing material being applied to the lens within predetermined areas, the viewing material forms an image. The system also includes the viewing material being a color pigment having a reflector core that reflects the incident light at the second angular range within the predetermined areas. The system also includes the absorption components being located within and outside the predetermined areas, the absorption components capturing energy from the incident light within the first angular range, and the absorption components being hidden at the second angular range.

In one embodiment, a system for improving the aesthetics of absorption components that harvest solar energy by displaying an image formed with structural ink and a lens that selectively displays the image while directing light for energy capture is disclosed. In one embodiment, the system includes a lenticular lens that directs incident light within a first angular range towards an absorption layer and a second angular range towards viewing material. The system also includes the viewing material being applied to the lenticular lens within predetermined areas, the viewing material forms an image. The system also includes the viewing material being a color pigment having a reflector core that reflects the incident light at the second angular range within the predetermined areas. The system also includes the absorption layer spanning within and outside the predetermined areas, the absorption layer capturing energy from the incident light within the first angular range, and the absorption layer being obstructed at the second angular range.

In one embodiment, a method for improving the aesthetics of absorption components that harvest solar energy by displaying an image formed with structural ink and a lens that selectively displays the image while directing light for energy capture is disclosed. In one embodiment, the method includes applying viewing material to a lens within predetermined areas, the viewing material forms an image and the lens directs incident light within a first angular range towards absorption components and a second angular range towards the viewing material. The method also includes the viewing material being a color pigment having a reflector core that reflects the incident light at the second angular range within the predetermined areas. The method also includes bonding the absorption components within and outside the predetermined areas, the absorption components capturing energy from the incident light within the first angular range, and the absorption components being hidden at the second angular range.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates an embodiment of a system having a lens controlling light towards components that absorb solar energy and viewing material formed with structural ink.

FIG. 2 illustrates an embodiment of layers having materials that form structural ink.

FIG. 3 illustrates an embodiment of an interlaced image formed with structural ink exhibiting visual effects.

### DETAILED DESCRIPTION

Systems, methods, and other embodiments associated with improving the aesthetics of absorption components that harvest solar energy by displaying an image formed with structural ink and a lens that selectively displays the image while directing light for energy capture are disclosed. In various implementations, systems use purpose-built reflective material and a reflective layer in displays for improving image quality. However, manufacturing costs can increase when integrating reflective materials. For example, printing reflective materials precisely can involve specialized printers. As such, costs and complexity increase when systems integrate image material and reflective material with absorption components.

Therefore, in one embodiment, a system has structural ink applied to a lens that forms an image in an alternating pattern with absorption components found below the lens. In one approach, the structural ink is printed on the lens in a juxtaposed pattern and the structural ink includes a reflector core that avoids applying reflective components to the system, thereby reducing material costs. Furthermore, the lens can be a lenticular lens that accurately directs incident light within different angular ranges for absorption and display of the image. The structural ink can be applied to the lens within predetermined areas following the alternating pattern for viewing the image vividly. In this way, the system improves aesthetics with the absorption components capturing energy from the incident light within a certain angular range and otherwise being hidden and obstructed by the image.

In another embodiment, the structural ink is a color pigment arranged by having a reflector layer and symmetrical layers using physical vapor deposition (PVD) where the structural ink produces colors through spectral interference. For instance, the symmetrical layers are alternating layers of dielectric (e.g., titanium dioxide (TiO₂)) and metallic materials. The reflector layer can be located at a middle of the symmetrical layers and prevent absorption from the dark color of absorption components for solar energy near the color pigment. This improves image vividity through increasing reflectivity by controlling light interference. In yet another approach, the system uses atomic layer deposition (ALD) to form the structural ink by encapsulating a reflector core (e.g., aluminum) near metallic material symmetrically. Thus, the system provides high reflectivity at a certain angular range and efficiency for energy harvesting over existing technologies while reducing complexity and material costs by production without a reflective component using structural ink.

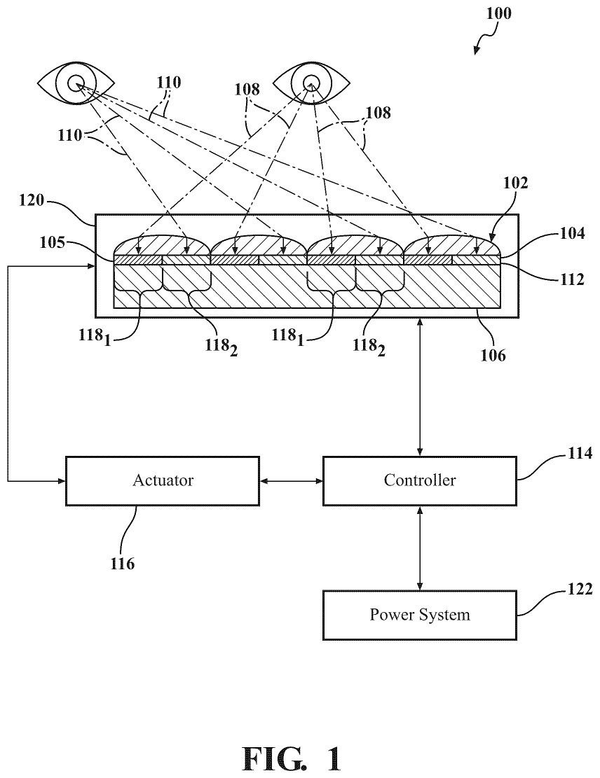

In certain implementations, the systems illustrated in FIGS. 1-3 also include various elements. It will be understood that in various embodiments, the systems may have less than the elements shown in FIGS. 1-3. The systems can have any combination of the various elements shown in FIGS. 1-3. Furthermore, the systems can have additional elements to those shown in FIGS. 1-3. In some arrangements, the systems may be implemented without one or more of the elements shown in FIGS. 1-3. While the various elements are shown as being located within the systems in FIGS. 1-3, it will be understood that one or more of these elements can be located external to the systems. Furthermore, the elements shown may be physically separated by large distances.

FIG. 1 illustrates embodiments of a system 100 having a lens 102 controlling light towards components that absorb energy and viewing material formed with structural ink. The system 100 can include a lens 102 that directs incident light within a first angular range 108 for absorption and a second angular range 110 for displaying an image. Viewing material 104 applied to the lens 102 within predetermined areas as a color pigment can form the image. As further explained below, the viewing material 104 is the color pigment having a reflector core that reflects the incident light at the second angular range 110 within the predetermined areas. In one approach, absorption components 106 are located within and outside the predetermined areas and capture energy from the incident light within the first angular range 108. Otherwise, the absorption components 106 are hidden at the second angular range 110, thereby increasing the aesthetic appeal of the system 100.

In the examples given herein, the system 100 may be installed on a building façade, a vehicle, a billboard, etc., for absorbing solar energy at a first angular range 108 while exhibiting the viewing material 104 forming an image at a second angular range 110. The lens 102 can transmit and direct incident light within the first angular range 108 for absorption and the second angular range 110 toward the viewing material 104. Furthermore, the absorption components 106 can be solar cells, an absorption layer, etc., that capture energy from the incident light within the first angular range 108 while otherwise being completely hidden, partially hidden, unviewable, obstructed, etc., from sight at the second angular range 110. In one approach, subunits 118₁ and 118₂ can be areas associated with the lens 102.

Moreover, in another approach, the viewing material 104 is structural ink that is applied to the lens 102 within subunits 118₂ while the absorption components 106 are located outside the subunits 118₂. This arrangement can allow the absorption components 106 being exposed to incident light when transparent material 105 located outside the predetermined areas of subunits 118₂ within the subunits 118₁ transmit the incident light towards the absorption components. In this way, the system improves aesthetics through displaying an image and allows expansive installation areas while efficiently capturing solar energy from light at certain incident angles.

The system 100 can have the lens 102 including the structural ink as viewing material bonded with the absorption components 106 using bonding material 112. For instance, the bonding material 112 is an optical adhesive that is clear for enhancing transparency while mitigating absorption losses during energy capture. This allows the system to improve appearances while maintaining energy benefits for a structure by absorbing energy at certain viewing angles and displaying an image at other viewing angles.

Regarding additional details about the system 100, angular ranges, bands, frequency ranges, etc., may be referenced as image bands that define angles at which the image (e.g., a black and white image, a color image, etc.) is viewable by a person, machine, etc. For instance, the viewing material 104 mimics an object design, communicates a message, advertises information, replicates an exterior façade, replicates roofing material, etc. The viewing material 104 can be one of a color, grayscale, black and white, etc., image. Furthermore, the viewing material 104 and the second angular range 110 can be image bands within one of predetermined areas, sections, etc., of the lens 102 associated with the subunits 118₁ and form an image. In this way, the system 100 includes the absorption components 106 capturing energy from the incident light within the first angular range 108 while being completely hidden, partially hidden, etc., at the second angular range 110 and the image being visible, thereby improving looks and designs.

Different forms of the lens 102 include functioning as a waveguide that optically controls and transmits incident light transparently toward the viewing material 104 and the absorption components 106. In one approach, the lens 102 is a lenticular layer, a lenticular film, a lenticular lens, a lenticular surface, etc., composed of one of a polymer, acrylic material, and polyethylene terephthalate (PET) that is fully flexible and transparent. Here, the lenticular lens can efficiently and clearly direct incident light towards the viewing material 104 and the absorption components 106. The lens can also be one of PET, PET-G, acrylic, polymer, and polystyrene that allows adaptation to structural shapes during installation unlike crystalline silicon. This flexibility allows the lens 102 and the absorption components 106 to curve and form a complete circle, thereby increasing installation capabilities.

The layers having the viewing material 104 and the absorption components 106 in FIGS. 1-3 are illustrations. For instance, the viewing material 104 and transparent material 105 can be part of the lens 102 and exhibit minimal thickness in a layer. In one example, the viewing material 104 is a micrometer, nanometers, etc., thin while the lens 102 is on a millimeter scale. This allows the absorption components 106 are bonded evenly and flatly to the lens 102 during manufacturing.

Regarding additional forms and structure, the lens 102 can include shaped features that is one of a hemisphere, a demilune, and a triangle associated with predetermined areas among the subunits 118₁ and 118₂. Furthermore, the lens 102 and the absorption components 106 (e.g., solar ink) can fully curve to form a complete circle, a circular shape (e.g., 270-360 degrees), a polygon, etc. The fully flexible features benefit applications for a vehicle hood, roofs, a bus stop, advertising, etc. Furthermore, the flexibility of the system 100 expands applications and installation capabilities on curved roofs, shaded canopies, building components, lampposts, vehicle panels, vehicle rooftops, etc. Here, an image formed by the viewing material 104 is viewable at certain angles while solar rays transmit toward the absorption components 106 at other angles. Accordingly, the system 100 improves the aesthetics of the building and other surfaces without obstructing solar rays, thereby increasing efficiency and energy harvesting.

Other embodiments include the lens 102 being a lenticular waveguide having patterned features that control and direct the transmission of incident light. For instance, the lenticular waveguide is an array of lenses that allows the visibility of the viewing material 104 at certain angles and generates optical effects. For example, the lenticular waveguide gives an image depth at certain colors and wavelengths. In another approach, the lens 102 is a lenticular waveguide having pixels that form one or more images. Thus, the system 100 can enhance the appearance of an image formed on the absorption components 106 that improves aesthetics during energy harvesting.

Regarding more details about the viewing material 104, applying the viewing material 104 as structural ink to the lens 102 can involve printing (e.g., directly printed) using a general printer, thereby reducing manufacturing complexity costs. Applications demanding high-resolution and precision can involve applying the viewing material 104 using a specialized printer. This approach can reduce ghosting and distortion from incident light being transmitted and absorbed by the absorption components 106 without interference, thereby improving image clarity.

In various implementations, the structural ink among the subunits 1182 found within the viewing material 104 form pixels for the image. For example, the pixels form an image viewable within certain angular ranges and transparent otherwise. As further explained below, the structural ink forming the pixels can be reflective and improve image viewing within the certain angular ranges.

The system 100 can include the viewing material 104 and the absorption components 106 forming a juxtaposed, alternating, etc., pattern. For example, a printer applies (e.g., direct printing) the structural ink in a juxtaposed pattern to the lens 102 (e.g., a lenticular lens) such that the viewing material 104 and the absorption components 106 are exposed to the incident light from different angular ranges. Here, the absorption components 106 are exposed to incident light at the first angular range 108. The structural ink forming the image is exposed to incident light at the second angular range 110.

The lens 102 can exhibit qualities that improve image quality and energy capture. For instance, the lens 102 is uniformly designed with various lenses per inch in different areas. Manufacturing for various design parameters can include extruding and rolling the lens 102. Adaptive designs allow the system 100 to have shapes and various curvatures for different installations and application demands. As previously explained, areas associated with the lens 102 can be designated with subunits 118₁ and 118₂. The subunits 118₁ can represent areas having parts of the absorption components 106 that capture energy at the first angular range 108. As previously explained, the subunits 118₂ have the viewing material 104 applied to the areas, such as through printing. Altering material and design properties of the lens 102 during manufacturing allow adapting different angles of incident light directed to the subunits 118₁ and 118₂ for energy capture by the absorption components 106 and illuminating the viewing material 104.

The widths of the viewing material 104 having structural ink, the absorption components 106, and the subunits 118₁ and 118₂ can vary depending upon demand for energy capture and visual design. For instance, the viewing material 104 has a first width X for light exposure to incident light. An area for light exposure to incident light by the absorption components 106 near the viewing material 102 has a second width Y. For example, the first width X and the second width Y comprise one of a 1:1 ratio, a 2:1 ratio, a 3:1 ratio, and a 1:3 ratio. A person of ordinary skill in the art understands that systems herein can also implement any ratio. As such, the system can be designed where increasing X increases information delivery and sharpness while increasing Y increases energy capture.

Additional applications for the system 100 can include the following. The system 100 can be integrated into a building for viewing an image while capturing solar energy. For example, the image displays one of an advertisement, an exterior façade, and roofing material. Here, solar rays at incident angles (e.g., 90-180 degrees) perpendicular to a building are transmitted toward the absorption components 106. This can involve diffusion through the lens 102 and varying absorption by mounting at an angle, vertically, etc. In one example, the system 100 displays a gray, blue, etc., image that mimics a façade at incident light (e.g., 0-90 degrees) from irradiation with reflected light. In other words, a pedestrian approaching the building sees an image formed with structural ink, whereas the absorption components 106 directly absorb solar energy at certain incident angles by unobstructed transmission through the lens 102. In this way, the system 100 improves aesthetics for the absorption components 106 while increasing power capture through expanding installation capabilities. Besides mimicking an object design, the image may also communicate a message, advertising information, etc. Accordingly, the system 100 increases available installation areas of systems for energy capture by attractive designs.

In FIG. 1A, controller 114 regulates energy draw from the device 120. The energy drawn is stored at power system 122. Similarly, a device, building, etc., can draw stored power from the power system 122. In various implementations, the controller 114 improves energy harvesting by adapting the orientation of the device 120 through different seasons using actuators 116. For example, the actuators 116 tilt the device 120 ten degrees toward the equator during the wintertime for capturing additional light more directly. Tilting can also generate visual effects on the image by varying direction of light travel through the lens 102. Thus, the controller 114 regulates power, enhances energy harvesting, and adapts visual effects of the device 120 through motion.

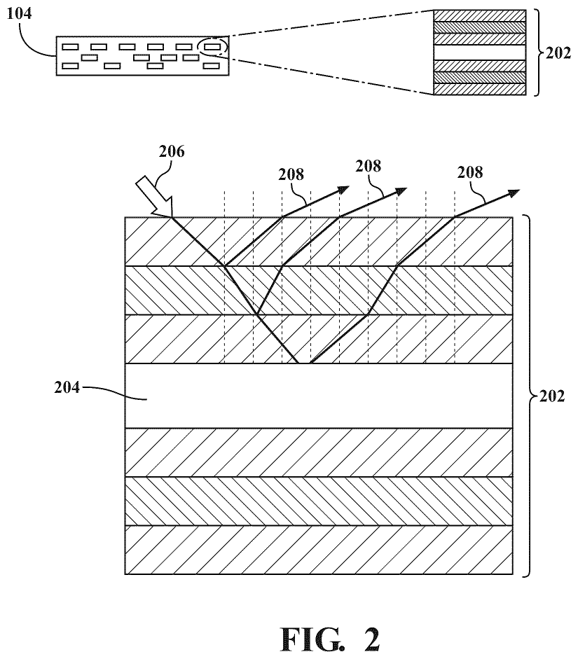

Now turning to FIG. 2, an embodiment of layers having materials that form structural ink 202 is illustrated. In one approach, the structural ink 202 forms a color pigment within an angular range, an image band, etc., by having a reflector core 204 and symmetrical layers and the structural ink 202 is applied to the lens 102. As further explained below, the reflector core 204 found within the color pigment avoids implementing independent reflective components within the system 100 and increased reflectivity improves image vividness. In this way, the system 100 allows for improved aesthetic integration with high retention of energy harvesting.

The viewing material 104 can have a plurality of the color pigments from the structural ink associated with forming an image. The structure and form of the structural ink 202 supplies vivid color and special effects (e.g., flip-flop) through spectral interference between the reflector core 204 and symmetrical layers from incident light 206. The reflector core 204 can be a layer located at a middle, center, etc., of a nanostructure made using PVD. The structural ink 202 manufactured with PVD can be inorganic giving enhanced and superior durability over organic pigments, particularly within exterior environments. The structural ink 202 reduces manufacturing costs by having the reflector core 204 that avoids the system applying (e.g., printing) additional reflective components for improving image quality. The reflector core 204 can prevent absorption from the dark color of the absorption components 106 (e.g., a solar cell) underneath, below, etc., and improves image vividity through increasing reflectivity. Such reflectivity can be controlled and tuned to a certain frequency band during application of the reflector core 204 and the symmetrical layers using PVD.

In various implementations, a symmetrical structure formed through PVD involves depositing Z layers (e.g., seven) within a chamber using vaporized gas. For example, a PVD machine deposits dielectric material and metallic material alternating in a symmetric form stacked around the reflector core 204 for the structural ink 202. For instance, a first layer is a dielectric (e.g., TiO₂)→a second layer is a metal→a third layer is a dielectric→a fourth layer is the reflector core 204→a fifth layer is a dielectric,→a sixth layer is a metal→a seventh layer is a dielectric. Regarding dimensions, the dielectric material, the metallic material, and the reflector core can have different thicknesses that allow various color emissions by the color pigment among different views and sides within the second angular range 110, thereby allowing angle-independence. Colors can change depending upon layer material and thickness associated with a pigment.

A machine can stack layers with a polymer having a sacrifice layer applied, then a dielectric, a metal, a dielectric, the reflector core 204, a dielectric, and a metal during a multi-layer process (e.g., seven layers). Applying a solvent can remove a sacrifice layer(s) to produce a film. In one approach, a machine then breaks the film into flakes and a flake can represent a color pigment that exhibits the symmetric structure of the structural ink 202. In another approach, dimensions of a flake can be nanometers in thickness and laterally in the micrometers, thereby exhibiting a minimal aspect ratio. Furthermore, material symmetry allows different orientations of the color pigments forming the viewing material 104 (e.g., a pixel). Otherwise, a viewer may see the reflector core 204 if the color pigment material is single-sided. Symmetry also allows seeing a similar pigment, pixel, etc., structure by the viewer at different sides, angles, etc., thereby providing viewing and angle independence.

In another approach, the structural ink 202 is formed using ALD manufacturing. In one approach, the structural ink 202 has the reflector core 204 comprising an aluminum material that reflects incident light 206 and the reflector core 204 is located adjacent to metallic material. The ALD process can involve the reflector core 204 and the metallic material being individually encapsulated as additional durability.

Manufacturing the structural ink 202 using ALD can involve applying an encapsulation layer (e.g., silicon dioxide (SiO₂)) to the reflector core 204 (e.g., aluminum) that is one of a flake, powder, etc. Processing involves depositing a dielectric on the encapsulating layer→applying a metal (e.g., TiO₂, Tungsten, etc.), etc. One approach to manufacturing involves encapsulating dielectric and metal layers. Unlike PVD which can demand sequential and separate layer deposition, ALD allows the simultaneous deposition of two symmetric layers surrounding a reflector core 204 in a unitary process. This simplifies the deposition and ensures uniform color visibility on multiple sides of a flake. Furthermore, ALD allows precise control over layer thickness, ensuring color remains consistent and angle-independent for viewers from various perspectives. Additionally, production of layers can continue up to Z layers and exhibit a minimal aspect ratio between thickness: width with thickness on a nanometer scale.

Incident light 206 and the reflected light 208 illuminate the color pigment at various visible bands when traveling through different layers of the structural ink 202 through spectral interference. The reflector core 204 increases the reflectivity of incident light at the second angular range 110 that enhances image quality and appearance for the system 100 involving the color pigment. Vividness is also improved by reducing ghosting through shielding the incident light 206 from reflecting off the absorption components 106. Accordingly, the system 100 improves the aesthetics of the absorption components 106 by displaying images at certain viewing angles according to interference and at other angles directly guiding solar rays toward the absorption components 106.

Enhanced reflectivity also prevents image distortion by containing light within the areas and reducing unintentional scattering. This also increases luminosity at different angles involving optical flip-flop that improves image vividness. For instance, the reflector core 204 insulates incident light from the absorption components 106 exhibiting darkness (e.g., black, deep blue, etc.). In other words, an image formed by the viewing material 104 can be distorted by light laterally absorbed from a color of absorption components 106 that otherwise would irradiate the image. Therefore, material with increased reflectivity redirects more incident light and reduces absorption by the absorption components 106, thereby reducing image distortion, improving image quality, and improving image resolution.

The system 100 also increases harvesting efficiency and reduces visual blurring through physical properties having controlled horizontal precision and adaptive printing. Furthermore, the structural ink can generate up to 90% reflectivity within a certain angular range from including the reflector core 204 rather than 10% reflectivity involving the color pigment without a reflective material below an image band. For energy harvesting, the system 100 can reach above 90% retention instead of 80% through other implementations. Therefore, the system 100 displays an image with the viewing material 104 that makes the absorption components 106 aesthetically pleasing and flexible for increasing applications and available installation areas, thereby improving energy capture.

In various implementations, a printer applies the structural ink 202 to the lens 102 within predetermined areas guided by the subunits 118₁ and 118₂. Here, the viewing material 104 formed with the structural ink 202 can be printed (e.g., directly printed) to the lens 102 for forming an image. The viewing material 104 forms the image and the lens 102 (e.g., a lenticular lens) directs incident light within the first angular range 108 for absorption and a second angular range 110 for displaying the image. As previously described, the viewing material 104 can include color pigment having a reflector core 204 that reflects incident light at the second angular range 110 within the predetermined areas. In one approach, bonding of the absorption components 106 within and outside the predetermined areas involves using an adhesive. Here, the absorption components 106 capture energy from the incident light within the first angular range 108. Meanwhile, the absorption components 106 are hidden from sight at the second angular range 110 through waveguide properties of the lens 102.

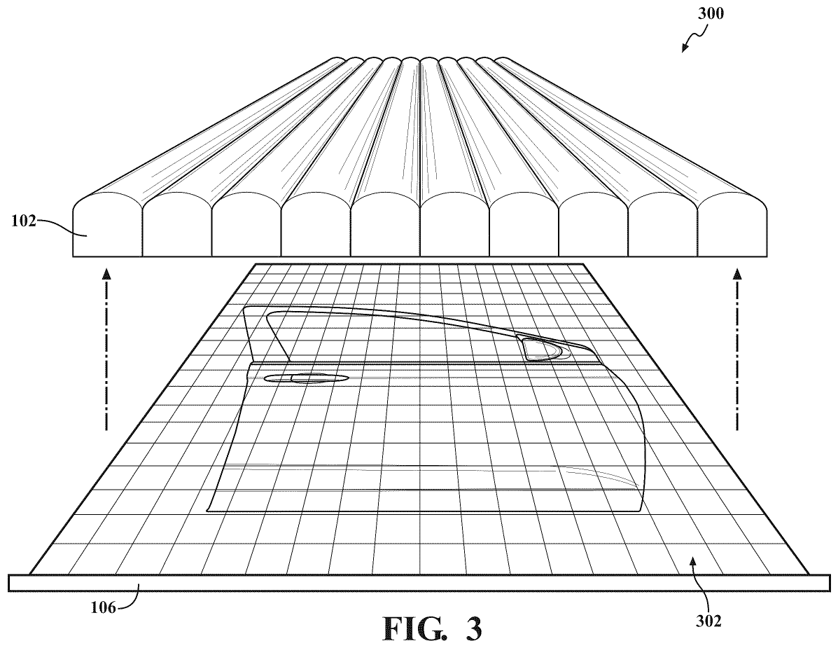

Concerning FIG. 3, an embodiment of an interlaced image 302 formed with structural ink exhibiting visual effects is illustrated. Here, the interlaced image 302 is applied to the lens 102 that selectively directs incident light for energy harvesting. The interlaced image 302 can include printed pixels that exhibit different images from one or more angular ranges, thereby generating special effects. At a capture band, the system 300 absorbs energy from incident light by the lens 102 directing angular viewing ranges to absorption components 106. Thus, the system 300 improves aesthetics through combining the interlaced image 302, absorption components 106, and a lens 102 that controls light transmission for special effects (e.g., color changes, transformative color, etc.) at certain viewing angles while maintaining efficient energy harvesting through reducing visual obstructions.

In one approach, the system 100 generates and outputs special visual effects using structural ink for an image. For instance, the system 100 controls color changes through spectral interference as incident light and reflected light travels through metallic and dielectric layers of different color pigments. Structural color that is omnidirectional displays the same color through different sides, angles, etc. However, tuning thickness and materials makes the structural color changeable by angle. As such, the system 100 displays unique special effects and impressions of an image on the solar cells when the system 100 exhibits color changes that are angle-dependent with the lens 102 spectral interference.

In another embodiment involving FIG. 3, an interlaced image 302 formed with structural ink exhibiting angle-dependent color changes is shown. While structural colors previously discussed are unique may exhibit angle-independence, structural color pigments can be made angle-dependent. For instance, a system selects layer materials with an elevated refractive index contrast. In this example, the interlaced image 302 is applied to a lens 102 that selectively directs incident light for energy harvesting. The image 302 can include printed pixels that display different visuals from varying angular ranges, thereby creating special visual effects as an improvement.

In one approach, the lens 102 directs angular light to absorption components 106 at a specific capture band that enables the system 300 to harvest energy efficiently while minimizing visual obstructions. This design integrates aesthetics and functionality by combining the interlaced image 302, absorption components 106, and the lens 102, which controls light transmission to create special effects at specific viewing angles while maintaining efficient energy harvesting capabilities.

In another approach, the system 100 generates and outputs special visual effects for images using structural ink. The color control is achieved during the pigment production process, where spectral interference is determined by adjusting the thickness of metallic and dielectric layers in a color pigment. Furthermore, a pigment produced with ALD exhibits natural reflection properties and the pigment is printer-compatible for various substrates. Accordingly, printing an image with structural ink allows having vivid colors on different substrates.

Detailed embodiments are disclosed herein. However, it is to be understood that the disclosed embodiments are intended as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Furthermore, the terms and phrases used herein are not intended to be limiting but rather to provide an understandable description of possible implementations. Various embodiments are shown in FIGS. 1-3, but the embodiments are not limited to the illustrated structure or application.

The flowcharts and block diagrams in the figures illustrate the architecture, functionality, and operation of possible implementations of systems, methods, and computer program products according to various embodiments. In this regard, a block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components, and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein.

The systems, components, and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises the features enabling the implementation of the methods described herein and, which when loaded in a processing system, is able to carry out these methods.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all combinations of one or more of the associated listed items. As an example, the phrase “at least one of A, B, and C” includes A, B, C, or any combination thereof (e.g., AB, AC, BC, or ABC).

Aspects herein can be embodied in other forms without departing from the spirit or essential attributes thereof. Accordingly, reference should be made to the following claims, rather than to the foregoing specification, as indicating the scope hereof.

1. A system comprising:
a lens that directs incident light within a first angular range towards absorption components and a second angular range towards viewing material;
the viewing material applied to the lens within predetermined areas, the viewing material forms an image;
the viewing material is a color pigment having a reflector core that reflects the incident light at the second angular range within the predetermined areas; and
the absorption components are located within and outside the predetermined areas, the absorption components capturing energy from the incident light within the first angular range, and the absorption components being hidden at the second angular range.

2. The system of claim 1 further comprising:
transparent material located outside the predetermined areas that transmit the incident light to the absorption components;
the viewing material is a structural ink that is printed onto the lens; and
the viewing material and the absorption components that are exposed to the incident light form an alternating pattern.

3. The system of claim 2, wherein:
the structural ink has dielectric material and metallic material alternating in a symmetric form stacked around the reflector core using physical vapor deposition (PVD) and the structural ink is angle-independent.

4. The system of claim 3, wherein:
the dielectric material and the metallic material have different thicknesses that change a color of the color pigment within the second angular range.

5. The system of claim 2, wherein:
the structural ink has the reflector core near metallic material in a symmetric form using atomic layer deposition (ALD), and the reflector core is an aluminum material and the structural ink is angle-independent; and
the reflector core and the metallic material are encapsulated with an oxide material.

6. The system of claim 2, wherein:
the lens and the absorption components curve to form a complete circle; and
the image displays one of an advertisement, an exterior façade, and roofing material.

7. The system of claim 1, wherein:
the viewing material has a first width that is exposed to the incident light and the absorption components near the viewing material has a second width that is exposed to the incident light; and
the first width and the second width comprise one of a 1:1 ratio, a 2:1 ratio, a 3:1 ratio, and a 1:3 ratio.

8. The system of claim 1, wherein:
the lens is a lenticular lens composed with one of a polymer and polyethylene terephthalate (PET) that forms a waveguide, the lenticular lens comprising one of a hemisphere, a demilune, and a triangular feature having the predetermined areas;
the lenticular lens adapts to a structural shape; and
the lenticular lens is transparent and flexible.

9. The system of claim 1, wherein:
the absorption components are solar cells that are bonded to the lens with an optical adhesive that is clear.

10. A system comprising:
a lenticular lens that directs incident light within a first angular range towards an absorption layer and a second angular range towards viewing material;
the viewing material applied to the lenticular lens within predetermined areas, the viewing material forms an image;
the viewing material is a color pigment having a reflector core that reflects the incident light at the second angular range within the predetermined areas; and
the absorption layer spanning within and outside the predetermined areas, the absorption layer capturing energy from the incident light within the first angular range, and the absorption layer being obstructed at the second angular range.

11. The system of claim 10 further comprising:
transparent material located outside the predetermined areas that transmit the incident light to the absorption layer;
the viewing material is a structural ink that is printed onto the lenticular lens; and
the viewing material and the absorption layer that are exposed to the incident light form a juxtaposed pattern.

12. The system of claim 11, wherein:
the structural ink has dielectric material and metallic material alternating in a symmetric form stacked around the reflector core using physical vapor deposition (PVD) and the structural ink is angle-independent.

13. The system of claim 12, wherein:
the dielectric material and the metallic material have different thicknesses that change a color of the color pigment within the second angular range.

14. The system of claim 11, wherein:
the structural ink has the reflector core near metallic material in a symmetric form using atomic layer deposition (ALD), and the reflector core is an aluminum material and the structural ink is angle-independent; and
the reflector core and the metallic material are encapsulated with an oxide material.

15. The system of claim 10, wherein:
the viewing material has a first width that is exposed to the incident light and the absorption layer near the viewing material has a second width that is exposed to the incident light; and
the first width and the second width comprise one of a 1:1 ratio, a 2:1 ratio, a 3:1 ratio, and a 1:3 ratio.

16. The system of claim 10, wherein:
the lenticular lens is composed with one of a polymer and polyethylene terephthalate (PET) that forms a waveguide, the lenticular lens comprising one of a hemisphere, a demilune, and a triangular feature having the predetermined areas;
the lenticular lens adapts to a structural shape; and
the lenticular lens is transparent and flexible.

17. A method comprising:
applying viewing material to a lens within predetermined areas, the viewing material forms an image and the lens directs incident light within a first angular range towards absorption components and a second angular range towards the viewing material;
the viewing material is a color pigment having a reflector core that reflects the incident light at the second angular range within the predetermined areas; and
bonding the absorption components within and outside the predetermined areas, the absorption components capturing energy from the incident light within the first angular range, and the absorption components being hidden at the second angular range.

18. The method of claim 17 further comprising:
transmitting the incident light to the absorption components by transparent material located outside the predetermined areas;
the viewing material is a structural ink that is printed onto the lens; and
the viewing material and the absorption components that are exposed to the incident light form an alternating pattern.

19. The method of claim 18 further comprising:
depositing dielectric material and metallic material alternating in a symmetric form stacked around the reflector core for the structural ink using physical vapor deposition (PVD) and the structural ink is angle-independent.

20. The method of claim 18 further comprising:
encapsulating the reflector core with metallic material and dielectric material in a symmetric form as the structural ink using atomic layer deposition (ALD), and the reflector core is an aluminum material and the structural ink is angle-independent.
